(19) United States
(12) Patent Application Publication
(10) Pub. No.: US 2026/0254446 A1
(43) Pub. Date: Aug. 27, 2026

(54) SEMICONDUCTOR DEVICE AND OPERATING METHOD OF THE SAME

(71) Applicant: SK hynix Inc., Gyeonggi-do (KR)

(72) Inventor: Sun Myung CHOI, Gyeonggi-do (KR)

(21) Appl. No.: 19/283,244

(22) Filed: Jul. 29, 2025

(30) Foreign Application Priority Data
Feb. 21, 2025 (KR) 10-2025-0022973

(51) Int. Cl. H03K 5/135; H03K 5/00; H03K 5/14

(52) U.S. Cl. CPC H03K 5/135; H03K 5/14; H03K 2005/00091

(57) ABSTRACT

The embodiments of the present disclosure relate to a semiconductor device including a monitoring circuit configured to monitor, during a boot-up period, a phase relationship between a reference signal and a flag signal to generate a monitoring signal; and a delay circuit configured to receive, during the boot-up period, the monitoring signal and a fuse signal and generate a fuse output signal which corresponds to the fuse signal or a delayed fuse signal depending on the phase relationship between the reference signal and the flag signal.

### CROSS-REFERENCE TO RELATED APPLICATION(S)

This application claims priority under 35 U.S.C. § 119 to Korean Patent Application No. 10-2025-0022973, filed on Feb. 21, 2025, the disclosure of which is incorporated herein by reference in its entirety.

### BACKGROUND

### 1. Field

Various embodiments of the present disclosure relate to a semiconductor design technique, and more particularly, to a semiconductor device that supports a boot-up mode of a plurality of semiconductor dies, and an operating method of the semiconductor device.

### 2. Description of the Related Art

As packaging technology rapidly develops, a semiconductor device in which a plurality of semiconductor dies are stacked, is being proposed in a single package. The semiconductor dies stacked in the semiconductor device transmit various signals and/or power sources through a plurality of through-die electrodes, for example, through silicon vias (TSVs), included therein.

The plurality of semiconductor dies included in the semiconductor device each include a fuse array. The fuse array loads a plurality of fuse signals during a boot-up period. That is, the plurality of fuse signals are outputted from the fuse array and latched in a plurality of latches.

Some of the target fuse signals among the plurality of fuse signals have to be sequentially generated according to an order assigned to the plurality of semiconductor dies, but the order may be reversed depending on operating conditions, for example, PVT (process, voltage and temperature) variations. When the order is reversed, a corresponding semiconductor die may unintentionally malfunction according to the target fuse signal or a signal derived from the target fuse signal.

### SUMMARY

Various embodiments of the present disclosure are directed to a semiconductor device capable of sequentially performing a boot-up operation of each of a plurality of semiconductor dies regardless of operating conditions, for example, PVT (process, voltage and temperature) variations, of each of the semiconductor dies while minimizing the use of through-die electrodes related to the boot-up operation, and an operating method of the semiconductor device.

In accordance with an embodiment of the present disclosure, a semiconductor device may include a monitoring circuit configured to monitor, during a boot-up period, a phase relationship between a reference signal and a flag signal to generate a monitoring signal; and a delay circuit configured to receive, during the boot-up period, the monitoring signal and a fuse signal and generate a fuse output signal which corresponds to the fuse signal or a delayed fuse signal depending on the phase relationship between the reference signal and the flag signal.

In accordance with an embodiment of the present disclosure, a semiconductor device may include a master die configured to generate, during a boot-up period, a first fuse output signal, which corresponds to a first fuse signal, regardless of a phase relationship between a first reference signal and a first flag signal; and a slave die configured to generate, during the boot-up period, a second fuse output signal which corresponds to a second fuse signal or a delayed second fuse signal depending on a phase relationship between a second reference signal and a second flag signal.

In accordance with an embodiment of the present disclosure, an operating method of a semiconductor device including a master die and a slave die may include sequentially loading, by the master die, first fuse signals based on a first oscillation signal; sequentially loading, by the slave die, second fuse signals based on a second oscillation signal; in response to a non-target second fuse signal loaded among the second fuse signals during a boot-up period, monitoring, by the slave die, a phase relationship between a second reference signal and a second flag signal to generate a second monitoring signal; and in response to a target second fuse signal loaded among the second fuse signals during the boot-up period, generating, by the slave die, a second fuse output signal corresponding to the target second fuse signal or a delayed target second fuse signal according to the second monitoring signal.

### BRIEF DESCRIPTION OF THE DRAWINGS

FIG. 1 is a block diagram illustrating a configuration of a semiconductor device in accordance with an embodiment of the present disclosure.

FIG. 2 is a block diagram illustrating a detailed configuration of a first setting circuit illustrated in FIG. 1, in accordance with an embodiment of the present disclosure.

FIG. 3 is a block diagram illustrating a detailed configuration of first and second enable circuits illustrated in FIG. 2, in accordance with an embodiment of the present disclosure.

FIG. 4 is a block diagram illustrating a detailed configuration of a first logic circuit illustrated in FIG. 2, in accordance with an embodiment of the present disclosure.

FIG. 5 is a block diagram illustrating a detailed configuration of a first monitoring circuit illustrated in FIG. 1, in accordance with an embodiment of the present disclosure.

FIG. 6 is a block diagram illustrating a detailed configuration of a second setting circuit illustrated in FIG. 1, in accordance with an embodiment of the present disclosure.

FIG. 7 is a block diagram illustrating a detailed configuration of third and fourth enable circuits illustrated in FIG. 6, in accordance with an embodiment of the present disclosure.

FIG. 8 is a block diagram illustrating a detailed configuration of a second logic circuit illustrated in FIG. 6, in accordance with an embodiment of the present disclosure.

FIG. 9 is a block diagram illustrating a detailed configuration of a second monitoring circuit illustrated in FIG. 1, in accordance with an embodiment of the present disclosure.

FIG. 10 is a timing diagram for describing an operation of a semiconductor device in accordance with an embodiment of the present disclosure.

FIG. 11 is a timing diagram for describing a process of generating a second monitoring signal illustrated in FIG. 10, in accordance with an embodiment of the present disclosure.

### DETAILED DESCRIPTION

Various embodiments of the present disclosure are described below with reference to the accompanying drawings, in order to describe in detail the embodiments of the present disclosure so that those with ordinary skill in art to which the present disclosure pertains may easily carry out the technical spirit of the present disclosure.

It will be understood that when an element is described as being “connected to” or “coupled to” another element, the connection may be direct, or it may be indirect through one or more intervening elements, either physically or electrically. In addition, it will also be understood that the terms “comprises,” “comprising,” “includes,” and “including” when used in this specification do not preclude the presence of one or more other elements, but may further include or have the one or more other elements, unless otherwise mentioned. In the description throughout the specification, some components are described in singular forms, but the present disclosure is not limited thereto, and it will be understood that the components may be formed in plural.

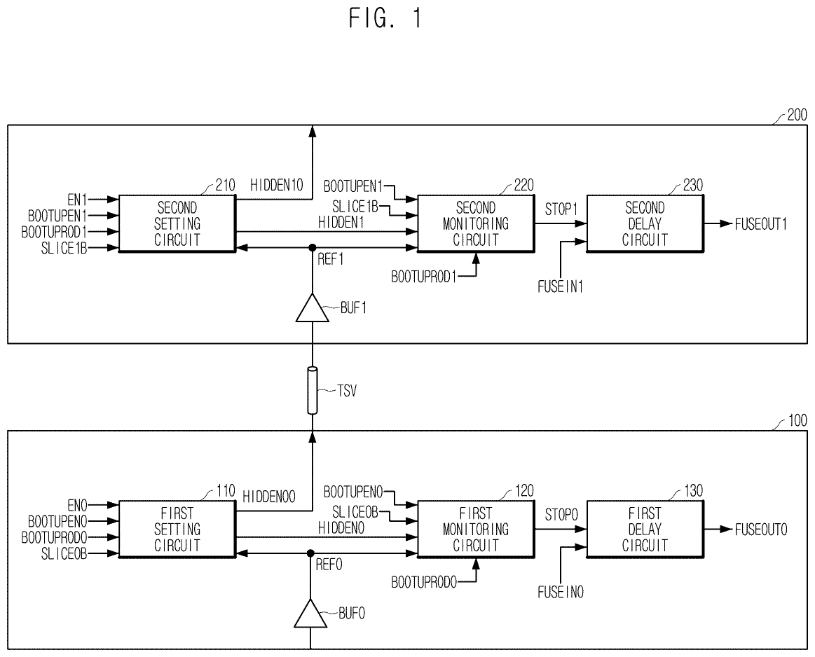

FIG. 1 is a block diagram illustrating a configuration of a semiconductor device in accordance with an embodiment of the present disclosure.

Referring to FIG. 1, the semiconductor device may include a master die 100 (i.e., master slice or master chip) and a slave die (i.e., slave slice or slave chip) 200. The master die 100 and the slave die 200 may be vertically stacked. In an embodiment, it is described as an example that one slave die 200 is included in the semiconductor device. However, the embodiments are not necessarily limited thereto, and a plurality of slave dies may be included in the semiconductor device.

The master die 100 may load a plurality of first fuse signals during a boot-up period. For example, although not illustrated, the master die 100 may transmit the plurality of first fuse signals from a first fuse array to first latches during the boot-up period. The first fuse array and the first latches may be included in the master die 100.

The master die 100 has to determine whether at least one fuse signal among the plurality of first fuse signals is delayed, but a series of processes for determining whether at least one fuse signal is delayed may be omitted depending on design. Hereinafter, the at least one fuse signal is referred to as a “target first fuse signal FUSEIN0”. For example, the master die 100 may determine whether the target first fuse signal FUSEIN0 is delayed, depending on a phase relationship between a first reference signal REF0 and a first flag signal HIDDEN0, which are to be described below. However, in an embodiment, the master die 100 may generate a first fuse output signal FUSEOUT0 corresponding to the target first fuse signal FUSEIN0, regardless of the phase relationship between the first reference signal REF0 and the first flag signal HIDDEN0, that is, without delay. This is because a boot-up operation of the master die 100 is designed to be performed before a boot-up operation of the slave die 200.

The master die 100 may provide the slave die 200 with a first hidden signal HIDDEN00, which corresponds to the first flag signal HIDDEN0, through a through-die via TSV. The through-die via TSV may be included in the master die 100, the slave die 200, or each of the master die 100 and the slave die 200, depending on design.

For example, the master die 100 may include a first buffer circuit BUF0, a first setting circuit 110, a first monitoring circuit 120, and a first delay circuit 130.

The first buffer circuit BUF0 may generate the first reference signal REF0 based on an input signal.

The first setting circuit 110 may generate the first flag signal HIDDEN0 and the first hidden signal HIDDEN00 based on a first oscillation signal BOOTUPROD0, a first boot-up signal BOOTUPEN0 and a first die identification signal SLICE0B. For example, the first setting circuit 110 may generate the first flag signal HIDDEN0 that is activated at least once during the boot-up period according to a predetermined quantity of settings. Hereinafter, for the convenience in description, an embodiment in which the first flag signal HIDDEN0 is activated twice during the boot-up period is described. The first setting circuit 110 may provide the slave die 200 with the first hidden signal HIDDEN00 corresponding to the first flag signal HIDDEN0.

The first monitoring circuit 120 may monitor the phase relationship between the first reference signal REF0 and the first flag signal HIDDEN0 and generate a first monitoring signal STOP0 corresponding to the monitoring result, based on the first boot-up signal BOOTUPEN0, the first die identification signal SLICE0B, the first flag signal HIDDEN0 and the first reference signal REF0. For example, the first monitoring circuit 120 may deactivate the first monitoring signal STOP0 during the boot-up period regardless of the phase relationship between the first flag signal HIDDEN0 and the first reference signal REF0 according to the first die identification signal SLICE0B corresponding to the master die 100.

The first delay circuit 130 may generate the first fuse output signal FUSEOUT0 based on the first monitoring signal STOP0 and the target first fuse signal FUSEIN0. For example, the first delay circuit 130 may generate the target first fuse signal FUSEIN0 as the first fuse output signal FUSEOUT0 without delay. Because the first monitoring signal STOP0 is deactivated during the boot-up period, the first delay circuit 130 may generate the first fuse output signal FUSEOUT0 corresponding to the target first fuse signal FUSEIN0 during the boot-up period. For example, the first delay circuit 130 may include a NOR gate that performs a NOR operation on the first monitoring signal STOP0 and the target first fuse signal FUSEIN0 and generates the first fuse output signal FUSEOUT0.

The input signal inputted to the master die 100 may float. According to one embodiment, although not clearly illustrated, the first buffer circuit BUF0 may generate the first reference signal REF0 having a fixed logic level, for example, a logic low level, regardless of the input signal based on the first die identification signal SLICE0B. According to another embodiment, the first setting circuit 110 and the first monitoring circuit 120 may each recognize the first reference signal REF0 as a signal having the fixed logic level, for example, the logic low level, based on the first die identification signal SLICE0B.

During the boot-up period, the slave die 200 may determine whether a target second fuse signal FUSEIN1 among a plurality of second fuse signals being loaded is delayed. Whether the target second fuse signal FUSEIN1 is delayed may be determined depending on a phase relationship between a second reference signal REF1 and a second flag signal HIDDEN1, which are described below. For example, during the boot-up period, the slave die 200 may generate a second fuse output signal FUSEOUT1, which corresponds to the target second fuse signal FUSEIN1 or a delayed second target fuse signal, depending on the phase relationship between the second reference signal REF1 and the second flag signal HIDDEN1. The delayed target second fuse signal may correspond to a signal obtained by delaying the target second fuse signal FUSEIN1.

The slave die 200 may use the first hidden signal HIDDEN00 provided from the master die 100 as the second reference signal REF1. The second reference signal REF1 may be a signal obtained by buffering the first hidden signal HIDDEN00 by a second buffer circuit BUF1.

For example, the slave die 200 may include the second buffer circuit BUF1, a second setting circuit 210, a second monitoring circuit 220, and a second delay circuit 230.

The second buffer circuit BUF1 may generate the second reference signal REF1 based on the first hidden signal HIDDEN00.

The second setting circuit 210 may generate the second flag signal HIDDEN1 and a second hidden signal HIDDEN10 based on a second oscillation signal BOOTUPROD1, a second boot-up signal BOOTUPEN1, a second die identification signal SLICE1B and the second reference signal REF1. For example, the second setting circuit 210 may generate the second flag signal HIDDEN1 that is activated at least once during the boot-up period according to the predetermined quantity of settings. Hereinafter, for the convenience in description, an embodiment in which the second flag signal HIDDEN1 is activated twice during the boot-up period is described. The second setting circuit 210 may provide another slave die (not illustrated) with the second hidden signal HIDDEN10 corresponding to the second flag signal HIDDEN1.

The second monitoring circuit 220 may monitor the phase relationship between the second reference signal REF1 and the second flag signal HIDDEN1 and generate a second monitoring signal STOP1 corresponding to the monitoring result, based on the second boot-up signal BOOTUPEN1, the second die identification signal SLICE1B, the second flag signal HIDDEN1 and the second reference signal REF1. For example, the second monitoring circuit 220 may compare a phase of the second reference signal REF1 with a phase of the second flag signal HIDDEN1 and deactivate the second monitoring signal STOP1 when the phase relationship between the second reference signal REF1 and the second flag signal HIDDEN1 is normal. The normal relationship may refer to a state in which the phase of the second reference signal REF1 is ahead of the phase of the second flag signal HIDDEN1. In contrast, the second monitoring circuit 220 may activate the second monitoring signal STOP1 when the phase relationship between the second reference signal REF1 and the second flag signal HIDDEN1 is a reverse relationship. The reverse relationship may refer to a state in which the phase of the second flag signal HIDDEN1 is ahead of the phase of the second reference signal REF1.

The second delay circuit 230 may generate the second fuse output signal FUSEOUT1, which corresponds to the target second fuse signal FUSEIN1 or the delayed target second fuse signal, based on the second monitoring signal STOP1 and the target second fuse signal FUSEIN1. For example, the second delay circuit 230 may generate the second fuse output signal FUSEOUT1 corresponding to the target second fuse signal FUSEIN1 when the phase relationship between the second reference signal REF1 and the second flag signal HIDDEN1 is the normal relationship. On the other hand, the second delay circuit 230 may generate the second fuse output signal FUSEOUT1, which corresponds to the delayed target second fuse signal, when the phase relationship between the second reference signal REF1 and the second flag signal HIDDEN1 is the reverse relationship. For example, the second delay circuit 230 may include a NOR gate that performs a NOR operation on the second monitoring signal STOP1 and the target second fuse signal FUSEIN1 and generates the second fuse output signal FUSEOUT1.

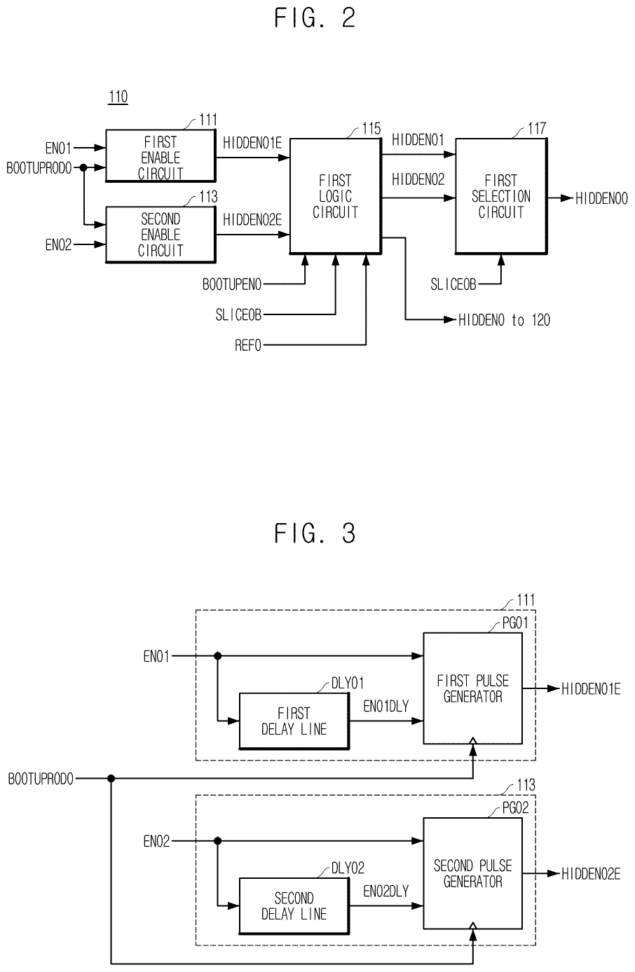

FIG. 2 is a block diagram illustrating a detailed configuration of the first setting circuit 110 illustrated in FIG. 1, in accordance with an embodiment of the present disclosure.

Referring to FIG. 2, the first setting circuit 110 may include a first enable circuit 111, a second enable circuit 113, a first logic circuit 115, and a first selection circuit 117.

The first enable circuit 111 may generate a first enable signal HIDDEN01E based on a first signal EN01 and the first oscillation signal BOOTUPROD0. For example, the first enable signal HIDDEN01E may be activated based on the first signal EN01 and deactivated based on the first oscillation signal BOOTUPROD0. The first enable circuit 111 is described in more detail below (refer to FIG. 3).

The second enable circuit 113 may generate a second enable signal HIDDEN02E based on a second signal EN02 and the first oscillation signal BOOTUPROD0. For example, the second enable signal HIDDEN02E may be activated based on the second signal EN02 and deactivated based on the first oscillation signal BOOTUPROD0. The second enable circuit 113 is described in more detail below (refer to FIG. 3).

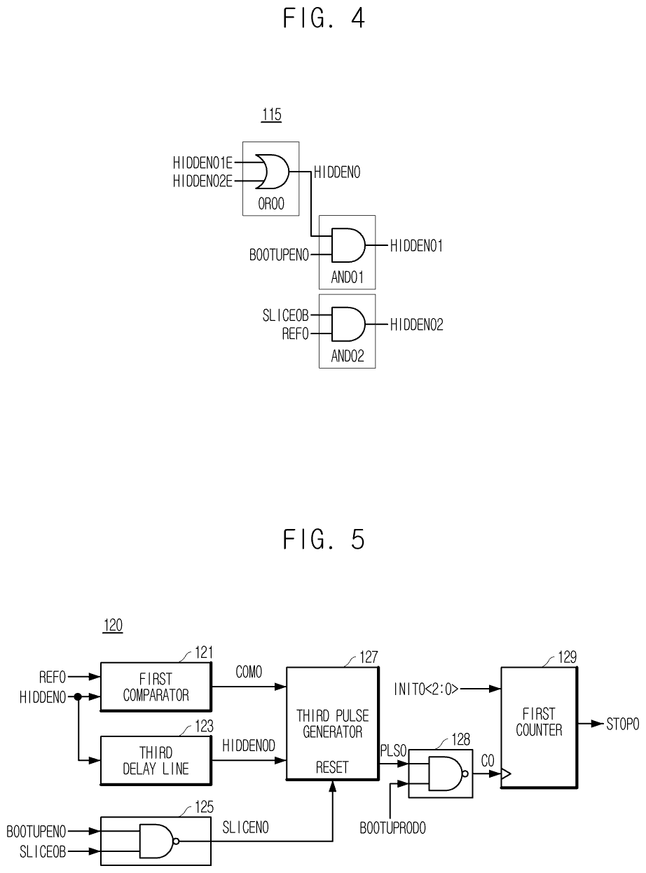

The first logic circuit 115 may perform a logic operation on the first and second enable signals HIDDEN01E and HIDDEN02E, the first boot-up signal BOOTUPEN0, the first die identification signal SLICE0B and the first reference signal REF0 and generate the first flag signal HIDDEN0 and first and second logic signals HIDDEN01 and HIDDEN02. The first logic circuit 115 is described in more detail below (refer to FIG. 4).

The first selection circuit 117 may generate the first hidden signal HIDDEN00 based on the first and second logic signals HIDDEN01 and HIDDEN02 and the first die identification signal SLICE0B. For example, the first selection circuit 117 may output the first logic signal HIDDEN01, which corresponds to the first flag signal HIDDEN0, among the first and second logic signals HIDDEN01 and HIDDEN02 as the first hidden signal HIDDEN00 based on the first die identification signal SLICE0B.

FIG. 3 is a block diagram illustrating a detailed configuration of the first and second enable circuits 111 and 113 illustrated in FIG. 2, in accordance with an embodiment of the present disclosure.

Referring to FIG. 3, the first enable circuit 111 may include a first delay line DLY01 and a first pulse generator PG01.

The first delay line DLY01 may delay the first signal EN01 and generate a first delayed signal EN01DLY.

The first pulse generator PG01 may generate the first enable signal HIDDEN01E based on the first signal EN01, the first delayed signal EN01DLY and the first oscillation signal BOOTUPROD0. For example, the first pulse generator PG01 may operate in synchronization with the first delayed signal EN01DLY, activate the first enable signal HIDDEN01E based on the first signal EN01 and deactivate the first enable signal HIDDEN01E based on the first oscillation signal BOOTUPROD0.

The second enable circuit 113 may include a second delay line DLY02 and a second pulse generator PG02.

The second delay line DLY02 may delay the second signal EN02 and generate a second delayed signal EN02DLY.

The second pulse generator PG02 may generate the second enable signal HIDDEN02E based on the second signal EN02, the second delayed signal EN02DLY and the first oscillation signal BOOTUPROD0. For example, the second pulse generator PG02 may operate in synchronization with the second delayed signal EN02DLY, activate the second enable signal HIDDEN02E based on the second signal EN02 and deactivate the second enable signal HIDDEN02E based on the first oscillation signal BOOTUPROD0.

FIG. 4 is a block diagram illustrating a detailed configuration of the first logic circuit 115 illustrated in FIG. 2, in accordance with an embodiment of the present disclosure.

Referring to FIG. 4, the first logic circuit 115 may include a first logic gate OR00, a second logic gate AND01, and a third logic gate AND02.

The first logic gate OR00 may generate the first flag signal HIDDEN0 based on the first enable signal HIDDEN01E and the second enable signal HIDDEN02E. For example, the first logic gate OR00 may include an OR gate that performs an OR operation on the first enable signal HIDDEN01E and the second enable signal HIDDEN02E and outputs the first flag signal HIDDEN0.

The second logic gate AND01 may generate the first logic signal HIDDEN01 based on the first flag signal HIDDEN0 and the first boot-up signal BOOTUPEN0. For example, the second logic gate AND01 may include an AND gate that performs an AND operation on the first flag signal HIDDEN0 and the first boot-up signal BOOTUPEN0 and outputs the first logic signal HIDDEN01.

The third logic gate AND02 may generate the second logic signal HIDDEN02 based on the first die identification signal SLICE0B and the first reference signal REF0. For example, the third logic gate AND02 may include an AND gate that performs an AND operation on the first die identification signal SLICE0B and the first reference signal REF0 and outputs the second logic signal HIDDEN02.

FIG. 5 is a block diagram illustrating a detailed configuration of the first monitoring circuit 120 illustrated in FIG. 1, in accordance with an embodiment of the present disclosure.

Referring to FIG. 5, the first monitoring circuit 120 may include a first comparator 121, a third delay line 123, a first operator 125, a third pulse generator 127, a second operator 128, and a first counter 129.

The first comparator 121 may compare a phase of the first reference signal REF0 with a phase of the first flag signal HIDDEN0 and generate a first comparison signal COM0 corresponding to the comparison result.

The third delay line 123 may delay the first flag signal HIDDEN0 and generate a first delay signal HIDDEN0D.

The first operator 125 may generate a first reset signal SLICEN0 based on the first boot-up signal BOOTUPEN0 and the first die identification signal SLICE0B. For example, the first operator 125 may include a NAND gate.

The third pulse generator 127 may generate a first pulse signal PLS0 based on the first comparison signal COM0, the first delay signal HIDDEN0D and the first reset signal SLICEN0. For example, the third pulse generator 127 may operate in synchronization with the first delay signal HIDDEN0D and generate the first pulse signal PLS0 that is activated based on the first comparison signal COM0 and deactivated based on the first reset signal SLICEN0.

The second operator 128 may generate a first limited oscillation signal C0 based on the first pulse signal PLS0 and the first oscillation signal BOOTUPROD0. For example, the second operator 128 may include a NAND gate.

The first counter 129 may generate the first monitoring signal STOP0 based on a predetermined count information signal INIT0<2:0> and the first limited oscillation signal C0. For example, when the count information signal INIT0<2:0> is set to “3”, i.e., “011”, the first counter 129 may activate the first monitoring signal STOP0 based on first toggling of the first limited oscillation signal C0 and deactivate the first monitoring signal STOP0 based on third toggling of the first limited oscillation signal C0.

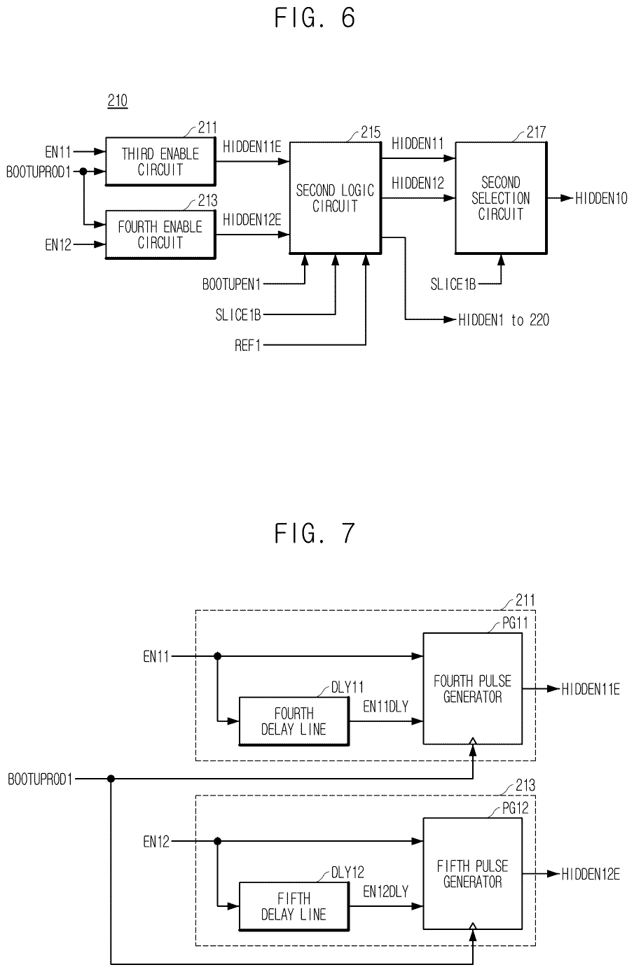

FIG. 6 is a block diagram illustrating a detailed configuration of the second setting circuit 210 illustrated in FIG. 1, in accordance with an embodiment of the present disclosure.

Referring to FIG. 6, the second setting circuit 210 may include a third enable circuit 211, a fourth enable circuit 213, a second logic circuit 215, and a second selection circuit 217.

The third enable circuit 211 may generate a third enable signal HIDDEN11E based on a third signal EN11 and the second oscillation signal BOOTUPROD1. For example, the third enable signal HIDDEN11E may be activated based on the third signal EN11 and deactivated based on the second oscillation signal BOOTUPROD1. The third enable circuit 211 is described in more detail below (refer to FIG. 7).

The fourth enable circuit 213 may generate a fourth enable signal HIDDEN12E based on a fourth signal EN12 and the second oscillation signal BOOTUPROD1. For example, the fourth enable signal HIDDEN12E may be activated based on the fourth signal EN12 and deactivated based on the second oscillation signal BOOTUPROD1. The fourth enable circuit 213 is described in more detail below (refer to FIG. 7).

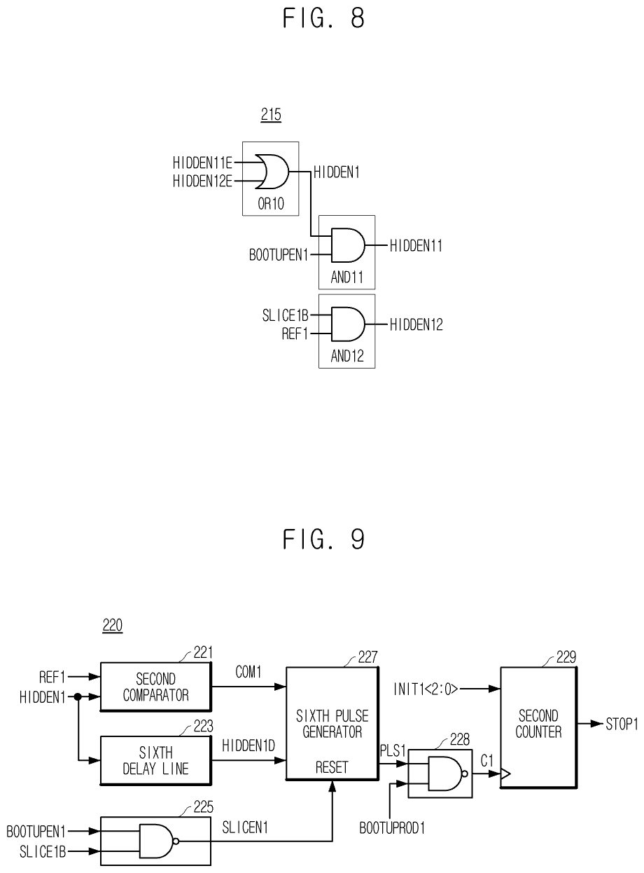

The second logic circuit 215 may perform a logic operation on the third and fourth enable signals HIDDEN11E and HIDDEN12E, the second boot-up signal BOOTUPEN1, the second die identification signal SLICE1B and the second reference signal REF1 and generate the second flag signal HIDDEN1 and the third and fourth logic signals HIDDEN11 and HIDDEN12. The second logic circuit 215 is described in more detail below (refer to FIG. 8).

The second selection circuit 217 may generate the second hidden signal HIDDEN10 based on the third and fourth logic signals HIDDEN11 and HIDDEN12 and the second die identification signal SLICE1B. For example, the second selection circuit 217 may output the fourth logic signal HIDDEN12, which corresponds to the first flag signal HIDDEN0, among the third and fourth logic signals HIDDEN11 and HIDDEN12 as the second hidden signal HIDDEN10 based on the second die identification signal SLICE1B.

Although not illustrated, when the semiconductor device according to an embodiment of the present disclosure further includes another slave die vertically stacked on the slave die 200, the another slave die may use the second hidden signal HIDDEN10 corresponding to the first flag signal HIDDEN0 as a reference signal.

FIG. 7 is a block diagram illustrating a detailed configuration of the third and fourth enable circuits 211 and 213 illustrated in FIG. 6, in accordance with an embodiment of the present disclosure.

Referring to FIG. 7, the third enable circuit 211 may include a fourth delay line DLY11 and a fourth pulse generator PG11.

The fourth delay line DLY11 may delay the third signal EN11 and generate a third delayed signal EN11DLY.

The fourth pulse generator PG11 may generate the third enable signal HIDDEN11E based on the third signal EN11, the third delayed signal EN11DLY and the second oscillation signal BOOTUPROD1. For example, the fourth pulse generator PG11 may operate in synchronization with the third delayed signal EN11DLY, activate the third enable signal HIDDEN11E based on the third signal EN11 and deactivate the third enable signal HIDDEN11E based on the second oscillation signal BOOTUPROD1.

The fourth enable circuit 213 may include a fifth delay line DLY12 and a fifth pulse generator PG12.

The fifth delay line DLY12 may delay the fourth signal EN12 and generate a fourth delayed signal EN12DLY.

The fifth pulse generator PG12 may generate the fourth enable signal HIDDEN12E based on the fourth signal EN12, the fourth delayed signal EN12DLY and the second oscillation signal BOOTUPROD1. For example, the fifth pulse generator PG12 may operate in synchronization with the fourth delayed signal EN12DLY, activate the fourth enable signal HIDDEN12E based on the fourth signal EN12 and deactivate the fourth enable signal HIDDEN12E based on the second oscillation signal BOOTUPROD1.

FIG. 8 is a block diagram illustrating a detailed configuration of the second logic circuit 215 illustrated in FIG. 6, in accordance with an embodiment of the present disclosure.

Referring to FIG. 8, the second logic circuit 215 may include a fourth logic gate OR10, a fifth logic gate AND11, and a sixth logic gate AND12.

The fourth logic gate OR10 may generate the second flag signal HIDDEN1 based on the third enable signal HIDDEN11E and the fourth enable signal HIDDEN12E. For example, the fourth logic gate OR10 may include an OR gate that performs an OR operation on the third enable signal HIDDEN11E and the fourth enable signal HIDDEN12E and outputs the second flag signal HIDDEN1.

The fifth logic gate AND11 may generate the third logic signal HIDDEN11 based on the second flag signal HIDDEN1 and the second boot-up signal BOOTUPEN1. For example, the fifth logic gate AND11 may include an AND gate that performs an AND operation on the second flag signal HIDDEN1 and the second boot-up signal BOOTUPEN1 and outputs the third logic signal HIDDEN11.

The sixth logic gate AND12 may generate the fourth logic signal HIDDEN12 based on the second die identification signal SLICE1B and the second reference signal REF1. For example, the sixth logic gate AND12 may include an AND gate that performs an AND operation on the second die identification signal SLICE1B and the second reference signal REF1 and outputs the fourth logic signal HIDDEN12.

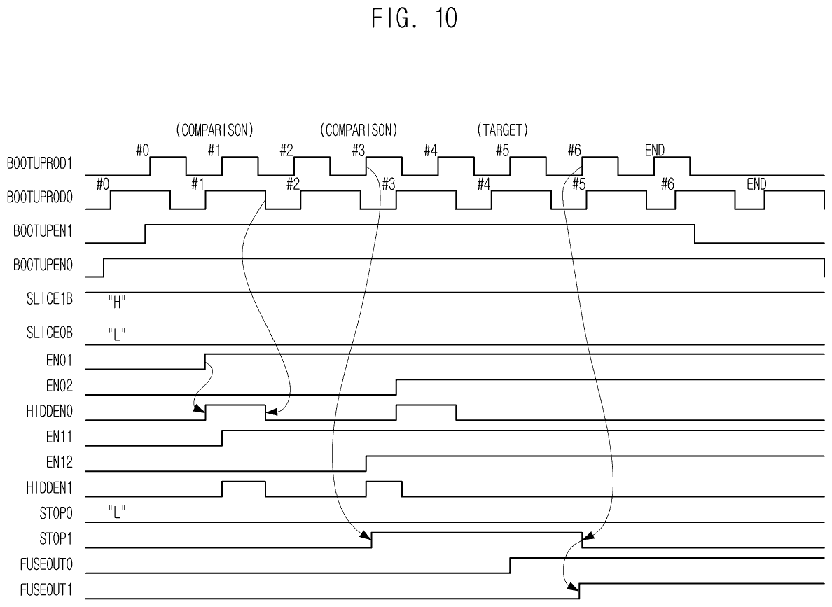

FIG. 9 is a block diagram illustrating a detailed configuration of the second monitoring circuit 220 illustrated in FIG. 1, in accordance with an embodiment of the present disclosure.

Referring to FIG. 9, the second monitoring circuit 220 may include a second comparator 221, a sixth delay line 223, a third operator 225, a sixth pulse generator 227, a fourth operator 228, and a second counter 229.

The second comparator 221 may compare the phase of the second reference signal REF1 with the phase of the second flag signal HIDDEN1 and generate a second comparison signal COM1 corresponding to the comparison result.

The sixth delay line 223 may delay the second flag signal HIDDEN1 and generate a second delay signal HIDDEN1D.

The third operator 225 may generate a second reset signal SLICEN1 based on the second boot-up signal BOOTUPEN1 and the second die identification signal SLICE1B. For example, the third operator 225 may include a NAND gate.

The sixth pulse generator 227 may generate a second pulse signal PLS1 based on the second comparison signal COM1, the second delay signal HIDDEN1D and the second reset signal SLICEN1. For example, the sixth pulse generator 227 may operate in synchronization with the second delay signal HIDDEN1D and generate the second pulse signal PLS1 that is activated based on the second comparison signal COM1 and deactivated based on the second reset signal SLICEN1.

The fourth operator 228 may generate a second limited oscillation signal C1 based on the second pulse signal PLS1 and the second oscillation signal BOOTUPROD1. For example, the fourth operator 228 may include a NAND gate.

The second counter 229 may generate the second monitoring signal STOP1 based on a predetermined count information signal INIT1<2:0> and the second limited oscillation signal C1. For example, when the count information signal INIT1<2:0> is set to “3”, i.e., “011”, the second counter 229 may activate the second monitoring signal STOP1 based on first toggling of the second limited oscillation signal C1 and deactivate the second monitoring signal STOP1 based on third toggling of the second limited oscillation signal C1.

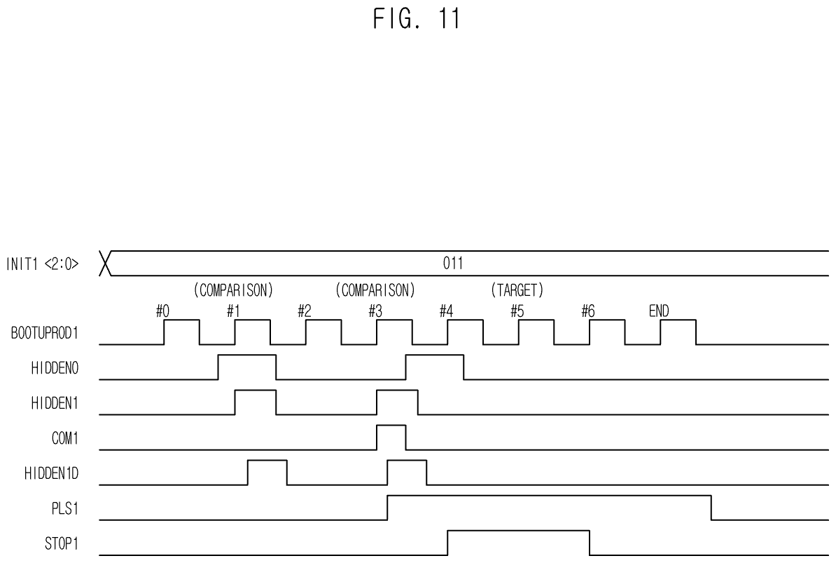

Hereinafter, an operation of the semiconductor device in accordance with an embodiment, which has the above-described configuration, is described with reference to FIGS. 10 and 11.

FIG. 10 is a timing diagram for describing an operation of the semiconductor device illustrated in FIG. 1, in accordance with an embodiment of the present disclosure.

Referring to FIG. 10, the master die 100 may sequentially load the first fuse signals based on the first oscillation signal BOOTUPROD0 during the boot-up period. The slave die 200 may sequentially load the second fuse signals based on the second oscillation signal BOOTUPROD1 during the boot-up period. The first oscillation signal BOOTUPROD0 and the second oscillation signal BOOTUPROD1 may have the same period and oscillate with a time difference, during the boot-up period. This is to prevent peak current. In an embodiment, it is described as an example that the first oscillation signal BOOTUPROD0 oscillates before the second oscillation signal BOOTUPROD1. That is, the second oscillation signal BOOTUPROD1 may be a signal delayed by a predetermined delay time from the first oscillation signal BOOTUPROD0.

Although the first oscillation signal BOOTUPROD0 and the second oscillation signal BOOTUPROD1 are generated to have substantially the same period, the first oscillation signal BOOTUPROD0 and the second oscillation signal BOOTUPROD1 may have different periods depending on operating conditions, for example, PVT (process, voltage and temperature) variations, as illustrated in FIG. 10. Accordingly, a phase of the first oscillation signal BOOTUPROD0 and a phase of the second oscillation signal BOOTUPROD1 may be reversed.

For example, in an embodiment, it is described that whether the first oscillation signal BOOTUPROD0 and the second oscillation signal BOOTUPROD1 are reversed is monitored when the second oscillation signal BOOTUPROD1 oscillates for a second time #1 and a fourth time #3, and a fuse signal that is loaded when the first oscillation signal BOOTUPROD0 and the second oscillation signal BOOTUPROD1 oscillate for a sixth time #5 is referred to as a “target fuse signal”.

As described above, because the first oscillation signal BOOTUPROD0 oscillates before the second oscillation signal BOOTUPROD1, the boot-up operation of the slave die 200 has to be delayed when the first oscillation signal BOOTUPROD0 and the second oscillation signal BOOTUPROD1 are reversed, which is described in more detail below.

The master die 100 may generate the first flag signal HIDDEN0 that is activated at least once according to a predetermined quantity of oscillations of the first oscillation signal BOOTUPROD0 during the boot-up period. For example, when the predetermined quantity of oscillations is set to “2” and “4,” the master die 100 may activate the first flag signal HIDDEN0 during a predetermined period when the first oscillation signal BOOTUPROD0 oscillates for the second time #1 during the boot-up period, and activate the first flag signal HIDDEN0 during the predetermined period when the first oscillation signal BOOTUPROD0 oscillates for the fourth time #3 during the boot-up period.

The master die 100 may generate the first hidden signal HIDDEN00 corresponding to the first flag signal HIDDEN0, based on the first die identification signal SLICE0B during the boot-up period. Although not illustrated, the first hidden signal HIDDEN00 may be a signal having the same waveform as the first flag signal HIDDEN0. The master die 100 may provide the slave die 200 with the first hidden signal HIDDEN00 during the boot-up period.

The slave die 200 may monitor a phase relationship between the second reference signal REF1 and the second flag signal HIDDEN1 in advance when a non-target second fuse signal among the second fuse signals is loaded and generate the second monitoring signal STOP1 corresponding to the monitoring result. This represents that the slave die 200 monitors the phase relationship between the second reference signal REF1 and the second flag signal HIDDEN1 in advance before the target second fuse signal FUSEIN1 among the second fuse signals is loaded. The second reference signal REF1 may correspond to the first hidden signal HIDDEN00. The slave die 200 may compare the phase of the second reference signal REF1 with the phase of the second flag signal HIDDEN1. When the phase relationship between the second reference signal REF1 and the second flag signal HIDDEN1 is a normal relationship, the slave die 200 may deactivate the second monitoring signal STOP1. When the phase relationship between the second reference signal REF1 and the second flag signal HIDDEN1 is a reverse relationship, the slave die 200 may activate the second monitoring signal STOP1.

For example, because second #1 oscillation time of the first oscillation signal BOOTUPROD0 is ahead of second #1 oscillation time of the second oscillation signal BOOTUPROD1, the slave die 200 may determine that the phase relationship between the second reference signal REF1 and the second flag signal HIDDEN1 is the normal relationship, and deactivate the second monitoring signal STOP1. In contrast, because fourth #3 oscillation time of the second oscillation signal BOOTUPROD1 is ahead of fourth #3 oscillation time of the first oscillation signal BOOTUPROD0, the slave die 200 may determine that the phase relationship between the second reference signal REF1 and the second flag signal HIDDEN1 is the reverse relationship, and activate the second monitoring signal STOP1.

The slave die 200 may generate the second fuse output signal FUSEOUT1 corresponding to the target second fuse signal FUSEIN1 or the delayed target second fuse signal, depending on the phase relationship between the second reference signal REF1 and the second flag signal HIDDEN1 when the target second fuse signal FUSEIN1 among the second fuse signals is loaded.

For example, based on the activated second monitoring signal STOP1, the slave die 200 may determine that the phase relationship between the second reference signal REF1 and the second flag signal HIDDEN1 is the reverse relationship when the second oscillation signal BOOTUPROD1 oscillates for the fourth time #3, and generate the second fuse output signal FUSEOUT1 corresponding to the delayed target second fuse signal. Although the target second fuse signal FUSEIN1 is loaded when the second oscillation signal BOOTUPROD1 oscillates for the sixth time #5, when the phase relationship between the second reference signal REF1 and the second flag signal HIDDEN1 is the reverse relationship, the slave die 200 may generate the second fuse output signal FUSEOUT1 corresponding to the delayed target second fuse signal when the second oscillation signal BOOTUPROD1 oscillates for a seventh time #6. In contrast, when the second monitoring signal STOP1 is deactivated, the slave die 200 may determine that the phase relationship between the second reference signal REF1 and the second flag signal HIDDEN1 is the normal relationship, and generate the second fuse output signal FUSEOUT1 corresponding to the target second fuse signal FUSEIN1 without delay.

FIG. 11 is a timing diagram for describing a process of generating the second monitoring signal STOP1 illustrated in FIG. 10, in accordance with an embodiment of the present disclosure.

Referring to FIG. 11, the slave die 200 may activate the second monitoring signal STOP1 during a predetermined period when the phase of the second oscillation signal BOOTUPROD1 reverses the phase of the first oscillation signal BOOTUPROD0. This is described in more detail as follows.

The second comparator 221 may compare the phase of the second reference signal REF1 with the phase of the second flag signal HIDDEN1 and generate the second comparison signal COM1 corresponding to the comparison result. For example, the second comparator 221 may activate the second comparison signal COM1 at fourth #3 oscillation time of the second oscillation signal BOOTUPROD1.

The sixth pulse generator 227 may generate the second pulse signal PLS1 based on the second comparison signal COM1, the second delay signal HIDDEN1D and the second reset signal SLICEN1. For example, the sixth pulse generator 227 may operate in synchronization with the second delay signal HIDDEN1D and generate the second pulse signal PLS1 that is activated based on the second comparison signal COM1 and deactivated based on the second reset signal SLICEN1.

The second counter 229 may generate the second monitoring signal STOP1 based on the predetermined count information signal INIT1<2:0> and the second limited oscillation signal C1. For example, when the count information signal INIT1<2:0> is set to “3”, i.e., “011”, the second counter 229 may activate the second monitoring signal STOP1 based on the first toggling of the second limited oscillation signal C1, that is, fifth #4 oscillation time of the second oscillation signal BOOTUPROD1, and deactivate the second monitoring signal STOP1 based on the third toggling of the second limited oscillation signal C1, that is, seventh #6 oscillation time of the second oscillation signal BOOTUPROD1.

According to an embodiment of the present disclosure, a minimum quantity of through-die electrodes related to a boot-up operation may be used, and boot-up operations of dies may be normally performed according to a predetermined order.

According to an embodiment of the present disclosure, a minimum quantity of through-die electrodes related to a boot-up operation may be used, which makes it possible to minimize an area allocated to the through-die electrodes. In addition, boot-up operations of a plurality of semiconductor dies may be sequentially performed, which makes it possible to improve operational reliability of a semiconductor device.

While the embodiments of the present disclosure have been illustrated and described with respect to specific embodiments, the disclosed embodiments are provided for the description and are not intended to be restrictive. Further, it is noted that the embodiments of the present disclosure may be achieved in various ways through substitution, change, and modification that fall within the scope of the following claims, as those skilled in the art will recognize in light of the present disclosure. The embodiments may be combined to form additional embodiments.

What is claimed is:

1. A semiconductor device comprising:
a monitoring circuit configured to monitor, during a boot-up period, a phase relationship between a reference signal and a flag signal to generate a monitoring signal; and
a delay circuit configured to receive, during the boot-up period, the monitoring signal and a fuse signal and generate a fuse output signal which corresponds to the fuse signal or a delayed fuse signal depending on the phase relationship between the reference signal and the flag signal.

2. The semiconductor device of claim 1, wherein the monitoring circuit is configured to:
compare a phase of the reference signal with a phase of the flag signal;
deactivate the monitoring signal when the phase of the second reference signal is ahead of the phase of the second flag signal; and
activate the monitoring signal when the phase of the second flag signal is ahead of the phase of the second reference signal.

3. The semiconductor device of claim 2, wherein the delay circuit is configured to:
generate the fuse output signal corresponding to the fuse signal when the phase of the second reference signal is ahead of the phase of the second flag signal; and
generate the fuse output signal corresponding to the delayed fuse signal when the phase of the second flag signal is ahead of the phase of the second reference signal.

4. The semiconductor device of claim 1, further comprising a setting circuit configured to generate, based on a boot-up signal and an oscillation signal, the flag signal which is activated at least once according to a predetermined quantity of settings.

5. The semiconductor device of claim 4, wherein the setting circuit includes:
at least one enable circuit configured to generate, based on the boot-up signal and the oscillation signal, at least one enable signal which corresponds to the predetermined quantity of settings; and
a logic circuit configured to perform a logic operation on the at least one enable signal to generate the flag signal.

6. The semiconductor device of claim 1, wherein the monitoring circuit includes:
a comparator configured to compare a phase of the reference signal with a phase of the flag signal to generate a comparison signal;
a pulse generator configured to generate a pulse signal based on the comparison signal and a reset signal;
an operator configured to generate a limited oscillation signal based on the pulse signal and an oscillation signal; and
a counter configured to generate the monitoring signal based on the limited oscillation signal and a count information signal.

7. A semiconductor device comprising:
a master die configured to generate, during a boot-up period, a first fuse output signal, which corresponds to a first fuse signal, regardless of a phase relationship between a first reference signal and a first flag signal; and
a slave die configured to generate, during the boot-up period, a second fuse output signal which corresponds to a second fuse signal or a delayed second fuse signal depending on a phase relationship between a second reference signal and a second flag signal.

8. The semiconductor device of claim 7, wherein:
the master die is configured to provide the slave die with a first hidden signal corresponding to the first flag signal; and
the slave die is configured to use the first hidden signal as the second reference signal.

9. The semiconductor device of claim 7, wherein the master die includes:
a first monitoring circuit configured to monitor the phase relationship between the first reference signal and the first flag signal to generate a first monitoring signal; and
a first delay circuit configured to receive the first monitoring signal and the first fuse signal and generate the first fuse output signal, which corresponds to the first fuse signal among the first fuse signal and a delayed first fuse signal, regardless of the phase relationship between the first reference signal and the first flag signal.

10. The semiconductor device of claim 9, wherein the master die further includes a first setting circuit configured to generate, based on a first boot-up signal and a first oscillation signal, the first flag signal which is activated at least once according to a predetermined quantity of settings.

11. The semiconductor device of claim 10, wherein the first setting circuit includes:
at least one first enable circuit configured to generate, based on the first oscillation signal, at least one first enable signal which corresponds to the predetermined quantity of settings;
a first logic circuit configured to perform a logic operation on the at least one first enable signal, the first boot-up signal and a first die identification signal to generate the first flag signal and at least one first logic signal; and
a first selection circuit configured to provide the slave die with a first hidden signal, which corresponds to the first flag signal, based on the at least one first logic signal and the first die identification signal.

12. The semiconductor device of claim 9, wherein the first monitoring circuit includes:
a first comparator configured to compare a phase of the first reference signal with a phase of the first flag signal to generate a first comparison signal;
a first pulse generator configured to generate a first pulse signal based on the first comparison signal and a first reset signal;
a first operator configured to generate a first limited oscillation signal based on the first pulse signal and a first oscillation signal; and
a first counter configured to generate the first monitoring signal based on the first limited oscillation signal and a first count information signal.

13. The semiconductor device of claim 9, wherein the slave die includes:
a second monitoring circuit configured to monitor the phase relationship between the second reference signal and the second flag signal to generate a second monitoring signal; and
a second delay circuit configured to receive the second monitoring signal and the second fuse signal and generate the second fuse output signal which corresponds to the second fuse signal and the delayed second fuse signal depending on the phase relationship between the second reference signal and the second flag signal.

14. The semiconductor device of claim 13, wherein the second monitoring circuit is configured to:
compare a phase of the second reference signal with a phase of the second flag signal;
deactivate the second monitoring signal when the phase of the second reference signal is ahead of the phase of the second flag signal; and
activate the second monitoring signal when the phase of the second flag signal is ahead of the phase of the second reference signal.

15. The semiconductor device of claim 14, wherein the second delay circuit is configured to:
generate the second fuse output signal corresponding to the second fuse signal when the phase of the second reference signal is ahead of the phase of the second flag signal; and
generate the second fuse output signal corresponding to the delayed second fuse signal when the phase of the second flag signal is ahead of the phase of the second reference signal.

16. The semiconductor device of claim 13, wherein the slave die further includes a second setting circuit configured to generate, based on a second boot-up signal and a second oscillation signal, the second flag signal which is activated at least once according to a predetermined quantity of settings.

17. The semiconductor device of claim 16, wherein the second setting circuit includes:
at least one second enable circuit configured to generate, based on the second oscillation signal, at least one second enable signal which corresponds to the predetermined quantity of settings;
a second logic circuit configured to perform a logic operation on the at least one second enable signal, the second boot-up signal and a second die identification signal to generate the second flag signal and at least one second logic signal; and
a second selection circuit configured to generate a second hidden signal, which corresponds to the second flag signal, based on the at least one second logic signal and the second die identification signal.

18. The semiconductor device of claim 13, wherein the second monitoring circuit includes:
a second comparator configured to compare a phase of the second reference signal with a phase of the second flag signal to generate a second comparison signal;
a second pulse generator configured to generate a second pulse signal based on the second comparison signal and a second reset signal;
a second operator configured to generate a second limited oscillation signal based on the second pulse signal and a second oscillation signal; and
a second counter configured to generate the second monitoring signal based on the second limited oscillation signal and a second count information signal.

19. An operating method of a semiconductor device including a master die and a slave die, the operating method comprising:
sequentially loading, by the master die, first fuse signals based on a first oscillation signal;
sequentially loading, by the slave die, second fuse signals based on a second oscillation signal;
in response to a non-target second fuse signal loaded among the second fuse signals during a boot-up period, monitoring, by the slave die, a phase relationship between a second reference signal and a second flag signal to generate a second monitoring signal; and
in response to a target second fuse signal loaded among the second fuse signals during the boot-up period, generating, by the slave die, a second fuse output signal corresponding to the target second fuse signal or a delayed target second fuse signal according to the second monitoring signal.

20. The operating method of claim 19, wherein the second oscillation signal is delayed by a predetermined delay time from the first oscillation signal.

21. The operating method of claim 19, wherein:
the master die is configured to provide the slave die with a first hidden signal corresponding to the first flag signal; and
the slave die is configured to use the first hidden signal as the second reference signal.

22. The operating method of claim 19, wherein:
the master die is configured to generate, based on the first oscillation signal, the first flag signal which is activated at least once according to a predetermined quantity of settings; and
the slave die is configured to generate, based on the second oscillation signal, the second flag signal which is activated at least once according to the predetermined quantity of settings.
